(19) United States
(12) Patent Application Publication
(10) Pub. No.: US 2025/0318372 A1
(43) Pub. Date: Oct. 9, 2025

(54) DISPLAY SUBSTRATE AND DISPLAY APPARATUS

(71) Applicants: Chengdu BOE Optoelectronics Technology Co., Ltd., Chengdu (CN); BOE Technology Group Co., Ltd., Beijing (CN)

(72) Inventors: Yang YAO, Beijing (CN); Taoran ZHANG, Beijing (CN); Hongwei MA, Beijing (CN); Du CHEN, Beijing (CN); Zailong MO, Beijing (CN); Da ZHOU, Beijing (CN); Xufeng WU, Beijing (CN); Xiaolong ZHENG, Beijing (CN); Yu SUN, Beijing (CN); Yanting LU, Beijing (CN); Kunlong LIU, Beijing (CN)

(21) Appl. No.: 18/869,682

(22) PCT Filed: Jan. 2, 2024
(86) PCT No.: PCT/CN2024/070083

§ 371 Date: Nov. 26, 2024

(51) Int. Cl. H10K 59/131; H10K 59/40

(52) U.S. Cl. CPC H10K 59/131; H10K 59/40

(57) ABSTRACT

A display substrate is provided, including: a base substrate, first pads in a first bonding area, a driver chip on the first pad, a connecting wire having one end connected to the first sub-pad, and an insulation protection portion. The first pads include a first sub-pad and a second sub-pad on a side of the first sub-pad close to a display area. An edge of the driver chip away from the display area protrudes from an edge of the first sub-pad. The insulation protection portion is arranged on a side of the connecting wire away from the base substrate and covers at least a portion of the connecting wire. An orthographic projection of the edge of the driver chip away from the display area on the base substrate falls within an orthographic projection of the insulation protection portion on the base substrate.

### CROSS-REFERENCE TO RELATED APPLICATION

This application is a Section 371 National Stage Application of International Application No. PCT/CN2024/070083, filed on Jan. 2, 2024, entitled “DISPLAY SUBSTRATE AND DISPLAY APPARATUS”.

### TECHNICAL FIELD

The present disclosure relates to the field of display technology, and in particular, to a display substrate and a display apparatus.

### BACKGROUND

With the development of display technology, “full screen display” has become a trend. Based on the increasingly extreme pursuit on the bezel width of the display apparatus, the encapsulation technology in which the driver chip is bonded to the display panel (namely chip on panel, abbreviated as COP) has emerged. According to this technology, the driver chip is directly bonded to the display panel, so that a lower end of the display panel may be bent to the back and thus bonded to the flexible printed circuit (FPC) on the back. In this way, the lower border of the display panel is permitted to be very narrow. However, how to ensure the bonding yield of driver chips using the COP encapsulation technology is one of the topics that display product developers pay attention to.

The above information disclosed in this section is only for understanding the background of the inventive concept of the present disclosure, thus the above information may include information that is not the prior art.

### SUMMARY

In an aspect, a display substrate is provided, including a display area and a peripheral area around the display area, the peripheral area including a first bonding area. The display substrate includes: a base substrate: first pads arranged on the base substrate and in the first bonding area, where the first pad includes a plurality of first sub-pads arranged at intervals and a plurality of second sub-pads arranged at intervals, and the plurality of second sub-pads are arranged on a side of the plurality of first sub-pads close to the display area; a driver chip arranged on the first pad, where an edge of the driver chip away from the display area protrudes from an edge of the first sub-pad; a connecting wire arranged on the base substrate, where one end of the connecting wire is electrically connected to the first sub-pad, and the other end of the connecting wire extends in a direction away from the display area; and an insulation protection portion arranged on a side of the connecting wire away from the base substrate, where the insulation protection portion covers at least a portion of the connecting wire. An orthographic projection of the edge of the driver chip away from the display area on the base substrate falls within an orthographic projection of the insulation protection portion on the base substrate.

According to some exemplary embodiments, the orthographic projection of the insulation protection portion on the base substrate has a first edge close to the display area and a second edge away from the display area, an orthographic projection of the driver chip on the base substrate has a third edge away from the display area, and the third edge is between the first edge and the second edge.

According to some exemplary embodiments, the display substrate further includes an organic insulation portion on a side of the connecting wire away from the base substrate, wherein the organic insulation portion covers a portion of the connecting wire, the organic insulation portion is spaced apart from the first sub-pad, an orthographic projection of the organic insulation portion on the base substrate has a fourth edge close to the display area, and the second edge is further away from the display area than the fourth edge; and/or an orthographic projection of the connecting wire on the base substrate has a fifth edge close to the display area, and the first edge is flush with the fifth edge.

According to some exemplary embodiments, the display substrate includes: a driving function layer on the base substrate, wherein the driving function layer comprises a plurality of driving metal layers; and a touch function layer on a side of the driving function layer away from the base substrate.

According to some exemplary embodiments, the connecting wire is arranged in the driving function layer, and the insulation protection portion is arranged in the touch function layer.

According to some exemplary embodiments, the touch function layer includes a touch base barrier layer on the driving function layer away from the base substrate, a first touch metal layer on a side of the touch base barrier layer away from the driving function layer, a touch insulation layer on a side of the first touch metal layer away from the touch base barrier layer, and a second touch metal layer on a side of the touch insulation layer away from the first touch metal layer. The insulation protection portion is arranged in at least one of the touch base barrier layer and the touch insulation layer.

According to some exemplary embodiments, the first sub-pad includes a first pad sub-portion and a second pad sub-portion on a side of the first pad sub-portion away from the base substrate. The first pad sub-portion is arranged in at least part of the driving metal layers, and the second pad sub-portion is arranged in the touch function layer.

According to some exemplary embodiments, the plurality of driving metal layers include: a first gate metal layer on the base substrate, a first source drain metal layer on a side of the first gate metal layer away from the base substrate, and a second source drain metal layer on a side of the first source drain metal layer away from the first gate metal layer. The first pad sub-portion is arranged in at least one of the first gate metal layer, the first source drain metal layer or the second source drain metal layer. Or, the plurality of driving metal layers include a first gate metal layer on the base substrate, a first source drain metal layer on a side of the first gate metal layer away from the base substrate, a second source drain metal layer on a side of the first source drain metal layer away from the first gate metal layer, and a third source drain metal layer on a side of the second source drain metal layer away from the first source drain metal layer; wherein the first pad sub-portion is arranged in at least one of the first gate metal layer, the first source drain metal layer, the second source drain metal layer or the third source drain metal layer.

According to some exemplary embodiments, the touch function layer includes a first touch metal layer and a second touch metal layer on a side of the first touch metal layer away from the base substrate, where the second pad sub-portion is arranged in at least one of the first touch metal layer and the second touch metal layer.

According to some exemplary embodiments, the first sub-pad is arranged in at least part of the driving metal layers.

According to some exemplary embodiments, the plurality of driving metal layers include: a first gate metal layer on the base substrate, a first source drain metal layer on a side of the first gate metal layer away from the base substrate, and a second source drain metal layer on a side of the first source drain metal layer away from the first gate metal layer, where the first sub-pad is arranged in at least one of the first gate metal layer, the first source drain metal layer or the second source drain metal layer. Or, the plurality of driving metal layers include a first gate metal layer on the base substrate, a first source drain metal layer on a side of the first gate metal layer away from the base substrate, a second source drain metal layer on a side of the first source drain metal layer away from the first gate metal layer, and a third source drain metal layer on a side of the second source drain metal layer away from the first source drain metal layer, where the first sub-pad is arranged in at least one of the first gate metal layer, the first source drain metal layer, the second source drain metal layer or the third source drain metal layer.

According to some exemplary embodiments, the connecting wire is arranged in the driving function layer, and the insulation protection portion is arranged in the driving function layer.

According to some exemplary embodiments, the connecting wire includes: a first sub-layer directly connected to the first sub-pad; and a second sub-layer on a side of the first sub-layer away from the base substrate, the second sub-layer being spaced apart from the first sub-pad and exposing a first portion of the first sub-layer. The insulation protection portion is arranged on a side of the first sub-layer away from the base substrate and covers at least the first portion of the first sub-layer.

According to some exemplary embodiments, the insulation protection portion extends from a surface of the first portion to an area between the first sub-layer and the second sub-layer, the insulation protection portion has a via hole on a side of the first portion away from the first sub-pad and arranged in the area between the first sub-layer and the second sub-layer, and the first sub-layer and the second sub-layer are connected through the via hole.

According to some exemplary embodiments, the driving function layer includes: a first source drain metal layer, a first passivation layer on a side of the first source drain metal layer away from the base substrate, and a second source drain metal layer on a side of the first passivation layer away from the first source drain metal layer, where the first sub-layer is arranged in the first source drain metal layer, the second sub-layer is arranged in the second source drain metal layer, and the insulation protection portion is arranged in the first passivation layer. Or, the driving function layer includes: a first source drain metal layer, a first passivation layer on a side of the first source drain metal layer away from the base substrate, a second source drain metal layer on a side of the first passivation layer away from the first source drain metal layer, a second passivation layer on a side of the second source drain metal layer away from the first passivation layer, and a third source drain metal layer on a side of the second passivation layer away from the second source drain metal layer, where the first sub-layer is arranged in the first source drain metal layer, the second sub-layer is arranged in the second source drain metal layer, and the insulation protection portion is arranged in the first passivation layer; or, the first sub-layer is arranged in the second source drain metal layer, the second sub-layer is arranged in the third source drain metal layer, and the insulation protection portion is arranged in the second passivation layer.

According to some exemplary embodiments, the display substrate further includes a sidewall protection portion covering at least a portion of a sidewall of the first sub-pad, and the sidewall protection portion is made of an insulation material.

According to some exemplary embodiments, the display substrate further includes a sidewall protection portion covering at least a portion of a sidewall of the first sub-pad, and the sidewall protection portion and the insulation protection portion are arranged in a same layer.

According to some exemplary embodiments, the peripheral area further includes a second bonding area on a side of the first bonding area away from the display area; the display substrate further includes a second pad arranged on the base substrate and in the second bonding area, the other end of the connecting wire is electrically connected to the second pad, and the insulation protection portion extends from the end of the connecting wire close to the first sub-pad to the other end of the connecting wire close to the second pad.

In another aspect, a display substrate is provided, including a display area and a peripheral area around the display area, and the peripheral area includes a first bonding area. The display substrate includes: a first pad arranged on a base substrate and in the first bonding area, where the first pad comprises a plurality of first sub-pads arranged at intervals and a plurality of second sub-pads arranged at intervals, and the plurality of second sub-pads are on a side of the plurality of first sub-pads close to the display area; a driver chip arranged on the first pad, where an edge of the driver chip away from the display area protrudes from an edge of the first sub-pad; a connecting wire arranged on the base substrate, where one end of the connecting wire is electrically connected to the first sub-pad, and the other end of the connecting wire extends in a direction away from the display area; an insulation protection portion on a side of the connecting wire away from the base substrate, where the insulation protection portion covers at least a portion of the connecting wire; and a sidewall protection portion covering at least a portion of a sidewall of the first pad, the sidewall protection portion being made of an insulation material. The insulation protection portion and the sidewall protection portion are arranged in a same layer, and an orthographic projection of the sidewall protection portion on the base substrate at least partially overlaps with an orthographic projection of the driver chip on the base substrate.

In yet another aspect, a display apparatus is provided, including the display substrate described above.

### BRIEF DESCRIPTION OF THE DRAWINGS

Features and advantages of the present disclosure will become more apparent by describing exemplary embodiments of the present disclosure with reference to the accompanying drawings in detail.

FIG. 1 shows a schematic cross-sectional diagram of a display substrate in the related art.

FIG. 2 schematically shows a schematic plan view of a display substrate according to an embodiment of the present disclosure.

FIG. 3 shows a partial schematic diagram of section B in FIG. 2.

FIG. 4 shows a schematic cross-sectional view of a display substrate along C-C′ in FIG. 3 according to some exemplary embodiments of the present disclosure.

FIG. 5 shows a schematic cross-sectional view of a display substrate along F-F′ in FIG. 2 according to some exemplary embodiments of the present disclosure.

FIG. 6 shows a schematic cross-sectional view of a display substrate along D-D′ in FIG. 3 according to some exemplary embodiments of the present disclosure.

FIG. 7 shows a schematic cross-sectional view of a display substrate along C-C′ in FIG. 3 according to some exemplary embodiments of the present disclosure.

FIG. 8 shows a schematic cross-sectional view of a display substrate along C-C′ in FIG. 3 according to some exemplary embodiments of the present disclosure.

FIG. 9 shows a schematic cross-sectional view of a display substrate along C-C′ in FIG. 3 according to some exemplary embodiments of the present disclosure.

FIG. 10 shows a schematic cross-sectional view of a display substrate along C-C′ in FIG. 3 according to some exemplary embodiments of the present disclosure.

FIG. 11 shows a schematic cross-sectional view of a display substrate along C-C′ in FIG. 3 according to some exemplary embodiments of the present disclosure.

### DETAILED DESCRIPTION OF EMBODIMENTS

In the following description, for ease of explanation, numerous specific details are set forth in order to provide a thorough understanding of the various exemplary embodiments. However, it is evident that the various exemplary embodiments may be implemented without these specific details or with one or more equivalent arrangements. In other examples, well-known structures and devices are shown in block diagram form in order to avoid unnecessarily obscuring the exemplary embodiments. Moreover, the various exemplary embodiments may be different, but are not necessarily exclusive. For example, the particular shapes, configurations and features of an exemplary embodiment may be used or implemented in another exemplary embodiment without departing from the inventive concept.

In the accompanying drawings, a size and a relative size of an element may be exaggerated for clarity and/or description. As such, sizes and relative sizes of various elements are not necessarily limited to those shown in the figures. When the exemplary embodiments can be implemented in a different way, the specific processes may be performed in a sequence different from the described sequence. For example, two consecutive processes descried may be performed substantially simultaneously or in a sequence reverse to the described sequence. In addition, the same reference signs indicate the same elements.

When an element is described as being “on”, “connected to” or “coupled to” another element, the element may be directly on, connected or coupled to the element or an intervening element may be present therebetween. However, when an element is described as being “directly on”, “directly connected to” or “directly coupled to” another element, there is no intervening element. Other terms and/or expressions used to describe a relationship between elements should be interpreted in a similar manner, such as, “between” versus “directly between”, “adjacent” versus “directly adjacent” or “on” versus “directly on”, etc. In addition, the term “connection” may refer to a physical connection, an electrical connection, a communication connection, and/or a fluid connection. In addition, X, Y, and Z axes are not limited to the three axes of a rectangular coordinate system, and may be interpreted in a broader sense. For example, X, Y, and Z axes may be perpendicular to one another, or may represent different directions that are not perpendicular to one another. According to the present disclosure, the expressions “at least one of X, Y or Z” and “at least one selected from a combination consisting of X, Y and Z” may be interpreted as X only, Y only, Z only, or any combination of two or more of X, Y or Z, such as XYZ, XYY, YZ and ZZ. As used herein, the term “and/or” includes any and all combinations of one or more of the related items listed.

It will be understood that, although the terms first, second and the like may be used to describe different elements, these elements should not be limited by these terms. These terms are only used to distinguish one element from another. For example, without departing from the scope of exemplary embodiments, a first element may be termed a second element, and, similarly, a second element may be termed a first element.

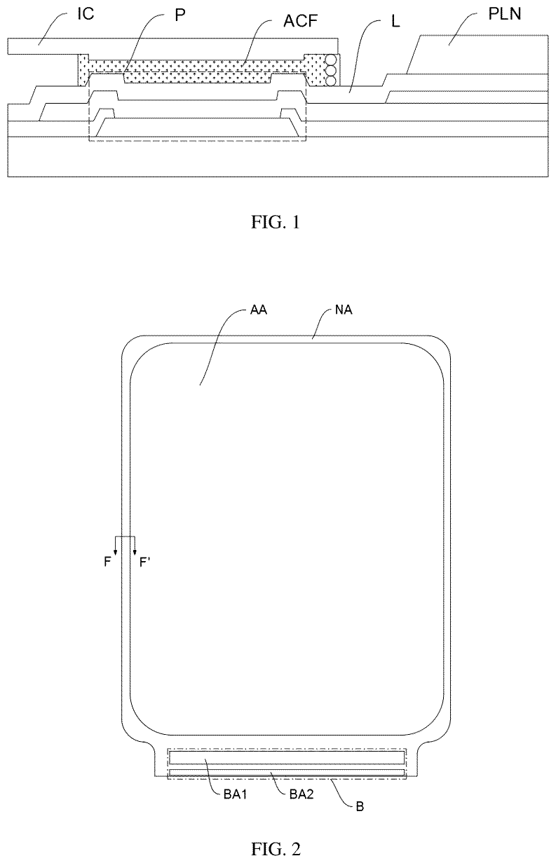

FIG. 1 shows a schematic cross-sectional diagram of a display substrate in the related art.

Referring to FIG. 1, a pad P used to bond a driver chip IC and an outer pad used to bond a flexible circuit board are carried out through a metal wire L. A planarization layer PLN is usually used to cover part of the metal wire L. However, in order to prevent the planarization layer PLN from affecting the bonding of the driver chip IC due to a large thickness of the planarization layer PLN, the planarization layer PLN is spaced apart from the pad P with a large spacing therebetween, so that a portion of the metal wire L close to the pad P is exposed.

Furthermore, when the driver chip IC is bonded, the housing of the driver chip IC extends beyond the pad P by a certain distance. The driver chip IC and the pad P are electrically connected through an anisotropic conductive film (ACF). The ACF is mainly composed of a resin adhesive and conductive particles. Conductive particles have anisotropy and are conductive when being pressed. Specifically, during the bonding process, pressure is applied to the driver chip IC, so as to press the conductive particles inside the ACF to achieve an electrical connection between the driver chip IC and the pad P.

However, the inventors find from researches that during the pressure bonding process, the conductive particles inside the ACF may be pushed to an edge of the driver chip IC, and if the conductive particles happen to get stuck between the housing of the driver chip IC and the exposed metal wire L, a short circuit between the housing of the driver chip IC and the metal wire L may be caused. Moreover, since the housing of the driver chip IC is usually negatively charged, for example, with a voltage of −7V, when the short-circuited metal wire L is a wire for a high-level signal, such as an analog power supply voltage (Analog VDD, AVDD) wire, the voltage signal on the short-circuited high-level signal wire will be pulled down, leading to a display defect.

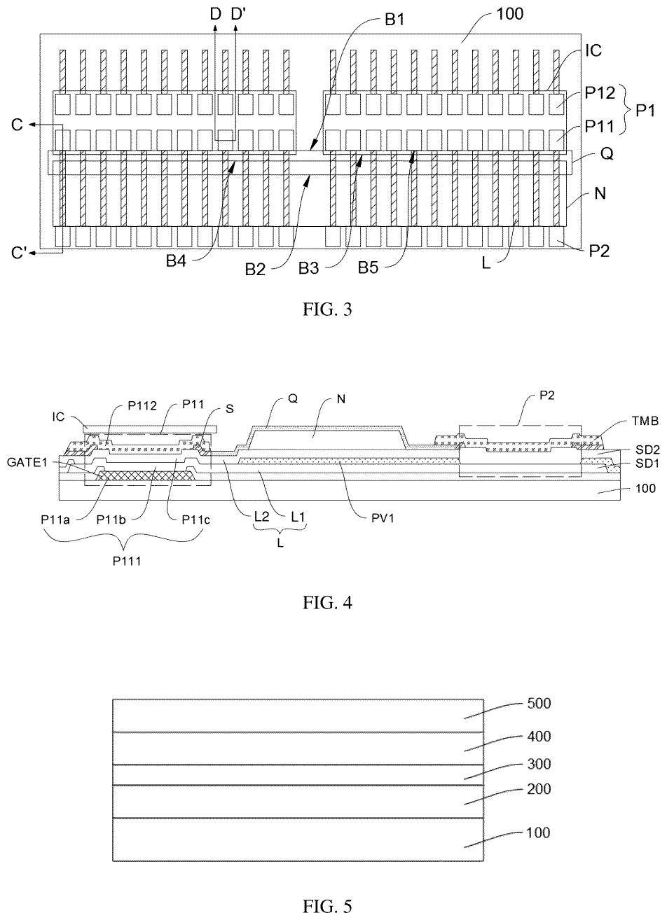

FIG. 2 schematically shows a schematic plan view of a display substrate according to an embodiment of the present disclosure. FIG. 3 shows a partial schematic diagram of section B in FIG. 2. FIG. 4 shows a schematic cross-sectional view of a display substrate along C-C′ in FIG. 3 according to some exemplary embodiments of the present disclosure.

Referring to FIG. 2, the display substrate includes a display area AA and a peripheral area NA around the display area AA. The peripheral area includes a first bonding area BA1 and a second bonding area BA2 spaced apart from each other. The second bonding area BA2 is on a side of the first bonding area BA1 away from the display area AA.

For example, the first bonding area BA1 is located outside a side of the display area AA. For example, the display substrate is applied to a mobile phone, and the first bonding area is on a lower side of the display area AA.

Referring to FIG. 3 and FIG. 4, the display substrate includes a base substrate 100, a first pad P1, a second pad P2, a driver chip IC, a connecting wire L, and an insulation protection portion Q.

The first pad P1 is arranged on the base substrate 100 and arranged in the first bonding area BA1. The first pads P1 include a plurality of first sub-pads P11 arranged at intervals and a plurality of second sub-pads P12 arranged at intervals. The plurality of second sub-pads P12 are arranged on a side of the plurality of first sub-pads P11 close to the display area AA. For example, the first sub-pad P11 serves as a signal input pad, and the second sub-pad P12 serves as a signal output pad.

The driver chip IC is arranged on the first pad P1 and is provided with pins. The bonding of the driver chip IC may be achieved by electrically connecting the pins to the first pads P1. For example, the pins include a signal input pin and a signal output pin. The signal input pin is electrically connected to the first sub-pad P11, and the signal output pin is electrically connected to the second sub-pad P12. An edge of the driver chip IC away from the display area protrudes from an edge of the first sub-pad P11.

The second pad P2 is arranged on the base substrate 100 and in the second bonding area BA2. For example, the display substrate has a plurality of second pads P2 arranged at intervals and a plurality of first sub-pads P11 arranged at intervals, the number of second pads P2 is the same as the number of the first sub-pads P11, and each of the second pads P2 corresponds to a respective one of the first sub-pads P11. The second pads P2 may be used for bonding to a flexible circuit board.

The connecting wire L is arranged on the base substrate 100. One end of the connecting wire L close to the display area AA is electrically connected to the first sub-pad P11, and the other end the connecting wire L extends in a direction away from the display area AA and is electrically connected to the second pad P2. The connecting wire L serves as a signal transmission wire between the first sub-pad P11 and the second pad P2.

The insulation protection portion Q is arranged on a side of the connecting wire L away from the base substrate 100 and covers at least a portion of the connecting wire L. An orthographic projection of the edge of the driver chip IC away from the display area AA (referring to the edge indicated by reference sign B3 in FIG. 3) on the base substrate 100 falls within an orthographic projection of the insulation protection portion Q on the base substrate 100, so as to avoid the problem of short circuit between the housing of the driver chip IC and the connecting wire L.

FIG. 5 shows a schematic cross-sectional view of a display substrate along F-F′ in FIG. 2 according to some exemplary embodiments of the present disclosure.

According to some exemplary embodiments, referring to FIG. 5, the display substrate includes a base substrate 100, a driving function layer 200, a light-emitting device layer 300, an encapsulation function layer 400, and a touch function layer 500. The driving function layer 200 is arranged on the base substrate 100, the light-emitting device layer 300 is arranged on a side of the driving function layer 200 away from the base substrate 100, the encapsulation function layer 400 is arranged on a side of the light-emitting device layer 300 away from the driving function layer 200, and the touch function layer 500 arranged is on a side of the encapsulation function layer 400 away from the light-emitting device layer 300. The first pad P1, the second pad P2, the connecting wire L and the insulation protection portion Q are arranged in at least one or some of the driving function layer 200, the light-emitting device layer 300, the encapsulation function layer 400 and the touch function layer 500 respectively.

For example, the driving function layer 200 includes a light shielding layer, an isolation layer, a first buffer layer, a first active layer, a first gate insulation layer, a first gate metal layer, a second gate insulation layer, a second gate metal layer, a first interlayer insulation layer, a second buffer layer, a second active layer, a third gate insulation layer, a third gate metal layer, a second interlayer insulation layer, a first source drain metal layer, a first passivation layer, a first planarization layer, a second source drain metal layer, a second planarization layer, a pixel defining layer and a spacer layer that are stacked on the base substrate in a direction away from the base substrate. For example, the first active layer is made of low-temperature polycrystalline silicon, and the second active layer is made of a material selected from metal oxide semiconductor materials, for example, the second active layer is made of indium gallium zinc oxide.

For example, the base substrate 100 may be a flexible base substrate, such as a plastic substrate made of polyvinyl ether phthalate, polycyclic aromatic compounds, polyimide (PI), polyethylene terephthalate (PET), polycarbonate (PC), cyclic olefin polymer (COP), cellulose acetate propionate (CAP), polyether sulfone (PES), polyacrylate (PAR), polyetherimide (PEI), polyethylene naphthalate (PEN), polyphenylene sulfide (PPS), polyallyl ester, cellulose triacetate (TAC) and other materials with excellent heat resistance and durability. The base substrate 100 may be a rigid base substrate, such as a glass substrate, which is not limited in the present disclosure.

For example, the driving function layer 200 includes a light shielding layer, an isolation layer, a first buffer layer, a first active layer, a first gate insulation layer, a first gate metal layer, a second gate insulation layer, a second gate metal layer, a first interlayer insulation layer, a second buffer layer, a second active layer, a third gate insulation layer, a third gate metal layer, a second interlayer insulation layer, a first source drain metal layer, a first passivation layer, a first planarization layer, a second source drain metal layer, a second passivation layer, a third source drain metal layer, a second planarization layer, a pixel defining layer and a spacer layer that are stacked on the base substrate in a direction away from the base substrate. For example, the first active layer is made of low-temperature polycrystalline silicon, and the second active layer is made of a material selected from metal oxide semiconductor materials, for example, the second active layer is made of indium gallium zinc oxide.

For example, materials of the isolation layer, the first buffer layer, the second buffer layer, the first gate insulation layer, the second gate insulation layer, the third gate insulation layer, the first interlayer insulation layer, the second interlayer insulation layer, the first passivation layer and the second passivation layer may include inorganic materials such as silicon oxide, silicon nitride and silicon oxynitride, and the film layer structure thereof may have a single-layer structure or a stacked structure, which is not limited in the present disclosure.

For example, the first planarization layer, the second planarization layer, the third planarization layer, the pixel defining layer and the spacer layer may be made of organic insulation materials such as polyacrylic acid resins, polyepoxy acrylic resins, photosensitive polyimide resins, polyester acrylates, polyurethane acrylic resins, phenolic epoxy acrylic resins, which is not limited in the present disclosure.

For example, the first gate metal layer, the second gate metal layer, the third gate metal layer, the first source drain metal layer, the second source drain metal layer and the third source drain metal layer may be made of materials suitable for dry etching, such as molybdenum, aluminum, and titanium. Optionally, these metal film layers may be a single-layer metal or a metal stack. For example, each gate metal layer is a single-layer of molybdenum metal, and each source drain metal layer is a triple-layer structure composed of titanium metal layer-aluminum metal layer-titanium metal layer.

For example, the light-emitting device layer 300 includes an anode layer, a light-emitting function layer and a cathode layer that are stacked on the driving function layer in a direction away from the driving function layer.

For example, the material of the anode layer may include at least one transparent conductive oxide material, including indium tin oxide, indium zinc oxide, zinc oxide, and the like. In addition, the anode layer may include a metal with high reflectivity as a reflective layer, such as silver. For example, the anode layer is a triple-layer structure composed of indium zinc oxide layer-silver layer-indium zinc oxide layer.

For example, the material of the light-emitting function layer may include small molecule organic materials or polymer molecule organic materials, which may be fluorescent luminescent materials or phosphorescent luminescent materials and may emit red, green, blue or white light.

For example, the cathode layer may include various conductive materials. For example, the cathode layer may include metal materials such as lithium, aluminum, magnesium, silver, or alloy materials composed of the aforementioned metal materials.

For example, function layers such as a hole injection layer and a hole transport layer may be further arranged between the anode layer and the light-emitting function layer. Function layers such as an electron injection layer and an electron transport layer may be further arranged between the cathode layer and the light-emitting layer.

For example, the encapsulation function layer 400 covers and seals the light-emitting device layer 300, thereby reducing or preventing degradation of the light-emitting device caused by moisture or oxygen in the environment. The encapsulation layer 400 may have a single-layer structure or a composite layer structure, where the composite layer structure includes a stack of inorganic and organic layers.

For example, the encapsulation layer 400 includes a first inorganic encapsulation layer, an organic encapsulation layer and a second inorganic encapsulation layer that are stacked in sequence.

For example, materials of the first inorganic encapsulation layer and the second inorganic encapsulation layer may include insulation materials such as silicon nitride, silicon oxide, and silicon oxynitride. Inorganic materials such as silicon nitride, silicon oxide and silicon oxynitride have high density and may prevent invasion of water, oxygen and the like. The material of the organic encapsulation layer may be polymer materials containing desiccants or polymer materials capable of blocking moisture, such as a polymer resin, so as to planarize the surface of the display substrate and reduce the stress of the first inorganic encapsulation layer and the second inorganic encapsulation layer, and may also include a water absorbing material such as a desiccant to absorb substances such as water and oxygen that invade the interior.

For example, the touch function layer 500 includes a first touch metal layer, a touch insulation layer and a second touch metal layer that are stacked on the encapsulation layer in a direction away from the encapsulation layer.

For example, the touch function layer 500 includes a touch base barrier layer between the first touch metal layer and the encapsulation layer.

For example, materials of the touch insulation layer and the touch base barrier layer may include inorganic materials such as silicon oxide, silicon nitride, and silicon oxynitride, and the touch insulation layer and the touch base barrier layer may have a single-layer structure or a stacked structure, which is not limited in the present disclosure.

According to some exemplary embodiments, referring to FIG. 3 and FIG. 4, the orthographic projection of the insulation protection portion Q on the base substrate 100 has a first edge B1 close to the display area AA and a second edge B2 away from the display area AA, and the orthographic projection of the driver chip IC on the base substrate 100 has a third edge B3 away from the display area AA. The third edge B3 is between the first edge B1 and the second edge B2.

According to some exemplary embodiments, referring to FIG. 3 and FIG. 4, the display substrate further includes an organic insulation portion N. The organic insulation portion N is on a side of the connecting wire L away from the base substrate 100 and covers a portion of the connecting wire L. The organic insulation portion N is spaced apart from the first sub-pad P11. An orthographic projection of the organic insulation portion N on the base substrate 100 has a fourth edge B4 close to the display area AA, and the second edge B2 is further away from the display area AA than the fourth edge. That is, the insulation protection portion Q is partially overlapped with the organic insulation portion N, and the end of the insulation protection portion Q away from the display area AA overlaps with the end of the organic insulation portion N close to the display area AA.

For example, the organic insulation portion N is arranged in the second planarization layer of the driving function layer, and the thickness of the insulation protection portion Q is much smaller than the thickness of the organic insulation portion N.

According to some exemplary embodiments, referring to FIG. 3 and FIG. 4, the orthographic projection of the connecting wire L on the base substrate 100 has a fifth edge B5 close to the display area AA, and the first edge B1 is flush with the fifth edge B5.

According to some exemplary embodiments, a portion of the connecting wire L on a side of the organic insulation portion N close to the display area AA is completely covered by the insulation protective portion Q.

According to some exemplary embodiments, referring to FIG. 4, the insulation protection portion Q extends from the end of the connecting wire L close to the first sub-pad P11 to the other end of the connecting wire L close to the second pad P2. All exposed surfaces of the connecting wire L are covered by the insulation protection portion Q.

According to some exemplary embodiments, referring to FIG. 4 and FIG. 5, the connecting wire L is arranged in the driving function layer 200, and the insulation protection portion Q is arranged in the touch function layer 500.

According to some exemplary embodiments, the insulation protection portion Q is arranged in the touch base barrier layer, or the insulation protection portion Q is arranged in the touch insulation layer, or the insulation protection portion Q is arranged in the touch insulation layer and the touch base barrier layer.

According to some exemplary embodiments, the first sub-pad P11 includes a first pad sub-portion P111 and a second pad sub-portion P112 on a side of the first pad sub-portion P111 away from the base substrate 100. The first pad sub-portion P111 is arranged in at least part of the driving metal layers, and the second pad sub-portion P112 is arranged in at least part of the touch function layer 500.

According to some exemplary embodiments, the first pad sub-portion P111 is arranged in at least one of the first gate metal layer, the first source drain metal layer or the second source drain metal layer.

For example, referring to FIG. 4, the first pad sub-portion P111 is arranged in the first gate metal layer, the first source drain metal layer and the second source drain metal layer. That is, the first pad sub-portion P111 has three stacked pad portions, including a first pad portion Plla on the base substrate 100, a second pad portion P11b on a side of the first pad portion Plla away from the base substrate 100, and a third pad portion Pllc on a side of the second pad portion P11b away from the base substrate 100. The first pad portion Plla is arranged in the first gate metal layer GATE1, the second pad portion P11b is arranged in the first source drain metal layer SD1, and the third pad portion Pllc is arranged in the second source drain metal layer SD2.

According to some exemplary embodiments, the first pad sub-portion P111 is arranged in at least one of the first gate metal layer, the first source drain metal layer, the second source drain metal layer or the third source drain metal layer.

For example, the first pad sub-portion P111 is arranged in the first gate metal layer, the first source drain metal layer, the second source drain metal layer and the third source drain metal layer. That is, the first pad sub-portion P111 has four stacked pad portions, including a first pad portion on the base substrate 100, a second pad portion on a side of the first pad portion away from the base substrate, a third pad portion on a side of the second pad portion away from the base substrate, and a fourth pad portion on a side of the third pad portion away from the base substrate. The first pad portion is arranged in the first gate metal layer, the second pad portion is arranged in the first source drain metal layer, the third pad portion is arranged in the second source drain metal layer, and the fourth pad portion is arranged in the third source drain metal layer.

According to some exemplary embodiments, the second pad sub-portion P112 is arranged in at least one of the first touch metal layer and the second touch metal layer. For example, referring to FIG. 4, the second pad sub-portion P112 is arranged in the second touch metal layer TMB.

According to some exemplary embodiments, referring to FIG. 4, the first pad sub-portion P111 is arranged in the first gate metal layer GATE1, the first source drain metal layer SD1 and the second source drain metal layer SD2, and the second pad sub-portion P112 is arranged in the second touch metal layer TMB. When the second touch metal layer TMB is formed by etching, a portion of the second touch metal layer TMB corresponding to an area of the first sub-pad P11 is retained, serving as the second pad sub-portion P112. Therefore, the increase of the bonding resistance, which is caused by the damage of the surface of the first pad sub-portion P111 away from the base substrate 100 due to exposure of this surface during the formation of the second touch metal layer TMB by etching, is avoided.

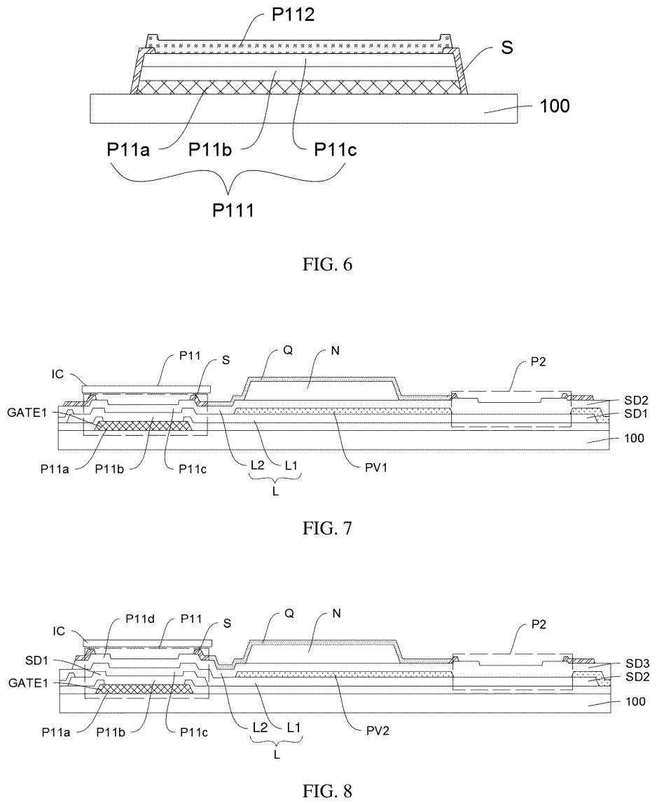

FIG. 6 shows a schematic cross-sectional view along D-D′ in FIG. 3.

According to some exemplary embodiments, referring to FIG. 6 and FIG. 4, the display substrate further includes a sidewall protection portion S, and the sidewall protection portion S covers at least a portion of the sidewall of the first sub-pad P11. The sidewall protection portion S is made of an insulation material, and an orthographic projection of the sidewall protection portion S on the base substrate at least partially overlaps with the orthographic projection of the driver chip IC on the base substrate.

It will be noted that each of the first source drain metal layer, the second source drain metal layer and the third source drain metal layer is usually configured as a stack of titanium layer-aluminum layer-titanium layer. When the first sub-pad P11 is arranged in at least one of these layers, since the etching rate of aluminum is significantly larger than the etching rate of titanium, an undercut structure may be formed at the sidewall of the first sub-pad P11 formed by etching, that is, the upper and lower titanium layers protrude from the middle aluminum layer. In the undercut structure, the upper titanium layer may collapse and fall off, causing a short circuit. Therefore, by providing the sidewall protection portion S made of insulation material on the sidewall of the first sub-pad P11 to cover the sidewall of the first sub-pad P11, it is possible to avoid the problem that the upper titanium layer in the undercut structure falls off.

According to some exemplary embodiments, the sidewall protection portion S is arranged in the touch base barrier layer, or the sidewall protection portion S is arranged in the touch insulation layer, or the sidewall protection portion S is arranged in the touch base barrier layer and the touch insulation layer.

According to some exemplary embodiments, the sidewall protection portion S and the insulation protection portion Q are arranged in the same layer. That is, the sidewall protection portion S and the insulation protection portion Q are formed by the same film formation process and patterning process. For example, both the sidewall protection portion S and the insulation protection portion Q are arranged in the touch base barrier layer, or both the sidewall protection portion S and the insulation protection portion Q are arranged in the touch insulation layer, or both the sidewall protection portion S and the insulation protection portion Q are arranged in the touch base barrier layer and the touch insulation layer.

According to some exemplary embodiments, referring to FIG. 6 and FIG. 4, the first pad sub-portion P111 is arranged in the first gate metal layer GATE1, the first source drain metal layer SD1 and the second source drain metal layer SD2. The second pad sub-portion P112 is arranged in the second touch metal layer TMB. The sidewall protection portion S and the insulation protection portion Q are both arranged in the touch base barrier layer and the touch insulation layer. As such, the sidewall protection portion S is arranged between the first pad sub-portion P111 and the second pad sub-portion P112 and covers the sidewall of the first pad sub-portion P111.

Further, considering factors such as the accuracy of the exposure process and the accuracy of the etching process during the patterning process, in order to ensure that the sidewall protection portion S may completely cover the sidewall of the first pad sub-portion P111, an end of the sidewall protection portion S away from the base substrate 100 is extended and arranged on the surface of the first pad sub-portion P111 away from the base substrate 100. That is, the end of the sidewall protection portion S away from the base substrate 100 is arranged between the first pad sub-portion P111 and the second pad sub-portion P112.

According to some exemplary embodiments, the first pad sub-portion is arranged in the first gate metal layer, the first source drain metal layer and the second source drain metal layer. The second pad sub-portion is arranged in the first touch metal layer. The sidewall protection portion and the insulation protection portion are both arranged in the touch insulation layer. The sidewall protection portion is arranged on a side of the second pad sub-portion away from the base substrate and covers the sidewall of the first pad sub-portion and the sidewall of the second pad sub-portion. In this case, the end of the sidewall protection portion away from the base substrate is arranged on the surface of the first sub-pad away from the base substrate. That is, the end of the sidewall protection portion away from the base substrate is not arranged inside the first sub-pad, thereby avoiding the problem of cracking of the first sub-pad during the pressure bonding process.

According to some exemplary embodiments, a sidewall protection portion may be provided at the sidewall of the second sub-pad, that is, the sidewall protection portion covers at least a portion of the sidewall of the second sub-pad. The sidewall protection portion at the sidewall of the second sub-pad is arranged with reference to the sidewall protection portion at the sidewall of the first sub-pad in the above-mentioned disclosed embodiments, which will not be repeated here.

According to some exemplary embodiments, referring to FIG. 4, the connecting wire L is a double-layer wire and includes a first sub-layer L1 and a second sub-layer L2 on a side of the first sub-layer L1 away from the base substrate 100.

According to some exemplary embodiments, the first sub-layer L1 is arranged in the first source drain metal layer and the second sub-layer L2 is arranged in the second source drain metal layer; or the first sub-layer L1 is arranged in the first source drain metal layer and the second sub-layer L2 is arranged in the third source drain metal layer: or the first sub-layer L1 is arranged in the second source drain metal layer and the second sub-layer L2 is arranged in the third source drain metal layer.

According to some exemplary embodiments, referring to FIG. 4, the first sub-layer L1 is arranged in the first source drain metal layer SD1, the second sub-layer L2 is arranged in the second source drain metal layer SD2, and a first passivation layer PV1 is arranged between the first sub-layer L1 and the second sub-layer L2.

According to some exemplary embodiments, the first passivation layer has a via hole, and the first sub-layer L1 and the second sub-layer L2 are connected in parallel through the via hole, so as to reduce the impedance of the connecting wire L.

According to some exemplary embodiments, the second pad P2 is arranged in at least part of the driving function layer 200, or the second pad P2 is arranged in at least some layers of the driving function layer 200 and touch function layer 500.

According to some exemplary embodiments, referring to FIG. 4, the second pad P2 is arranged in the first source drain metal layer SD1, the second source drain metal layer SD2 and the second touch metal layer TMB.

According to some exemplary embodiments, a sidewall protection portion may be provided at the sidewall of the second pad P2.

FIG. 7 shows a schematic cross-sectional view of a display substrate along C-C′ in FIG. 3 according to some exemplary embodiments of the present disclosure.

According to some exemplary embodiments, referring to FIG. 7, the first sub-pad P11 is arranged only in the driving function layer 200, that is, the first sub-pad P11 is arranged in at least part of the driving metal layers.

According to some exemplary embodiments, the first sub-pad P11 is arranged in at least one of the first gate metal layer, the first source drain metal layer or the second source drain metal layer.

For example, referring to FIG. 7, the first sub-pad P11 is arranged in the first gate metal layer GATE1, the first source drain metal layer SD1 and the second source drain metal layer SD2. That is, the first sub-pad P11 has three stacked pad portions, including a first pad portion Plla on the base substrate 100, a second pad portion P11b on a side of the first pad portion Plla away from the base substrate 100, and a third pad portion Pllc on a side of the second pad portion P11b away from the base substrate 100. The first pad portion Plla is arranged in the first gate metal layer GATE1, the second pad portion P11b is arranged in the first source drain metal layer SD1, and the third pad portion Pllc is arranged in the second source drain metal layer SD2.

For the first sub-pad P11 of this structure, in order to avoid etching damage to the surface of the first sub-pad P11 during the formation of the second touch metal layer by etching, the manufacturing process for the display substrate is adjusted, where at least one of the touch base barrier layer and the touch insulation layer is adjusted to be formed through two patterning processes.

For example, a touch base barrier layer is formed through two patterning processes. In the first patterning process, a portion of the touch base barrier layer on the upper surface of the first sub-pad P11 is retained as an etching barrier structure. After the second touch metal layer is formed by etching, the portion of the touch base barrier layer on the upper surface of the first sub-pad P11 is removed by etching in the second patterning process.

According to some exemplary embodiments, the first sub-pad P11 is arranged in at least one of the first gate metal layer, the first source drain metal layer, the second source drain metal layer or the third source drain metal layer.

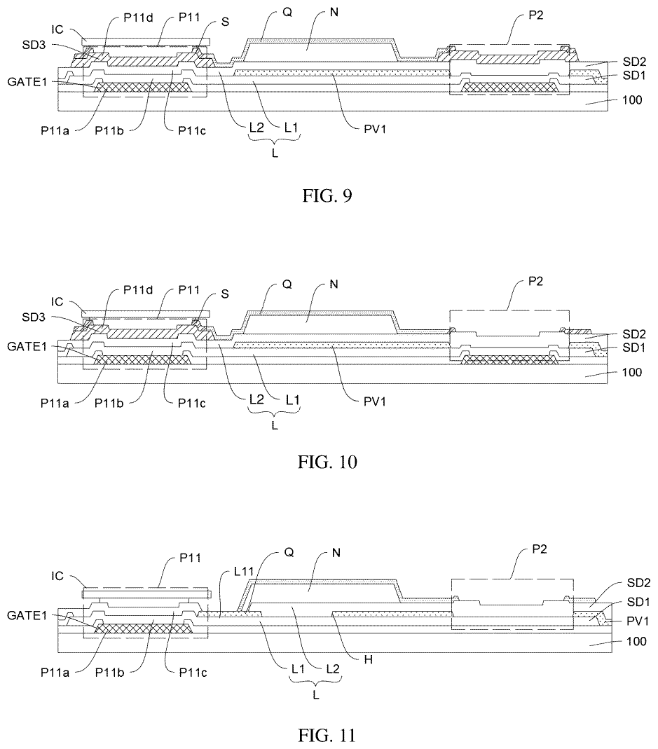

FIG. 8 shows a schematic cross-sectional view of a display substrate along C-C′ in FIG. 3 according to some exemplary embodiments of the present disclosure. FIG. 9 shows a schematic cross-sectional view of a display substrate along C-C′ in FIG. 3 according to some exemplary embodiments of the present disclosure. FIG. 10 shows a schematic cross-sectional view of a display substrate along C-C′ in FIG. 3 according to some exemplary embodiments of the present disclosure.

For example, referring to FIG. 8, FIG. 9 or FIG. 10, the first sub-pad P11 is arranged in the first gate metal layer GATE1, the first source drain metal layer SD1, the second source drain metal layer SD2 and the third source drain metal layer SD3. That is, the first sub-pad P11 has four stacked pad portions, including a first pad portion P11a on the base substrate 100, a second pad portion P11b on a side of the first pad portion P11a away from the base substrate 100, a third pad portion Pllc on a side of the second pad portion P11b away from the base substrate 100, and a fourth pad portion P11d on a side of the third pad portion P11c away from the base substrate 100. The first pad portion P11a is arranged in the first gate metal layer GATE1, the second pad portion P11b is arranged in the first source drain metal layer SD1, the third pad portion P11c is arranged in the second source drain metal layer SD2, and the fourth pad portion P11d is arranged in the third source drain metal layer SD3.

According to some exemplary embodiments, referring to FIG. 7 to FIG. 10, the display substrate further includes a sidewall protection portion S covering at least a portion the sidewall of the first sub-pad P11.

According to some exemplary embodiments, the sidewall protection portion S is arranged in the touch base barrier layer, or the sidewall protection portion S is arranged in the touch insulation layer, or the sidewall protection portion S is arranged in both the touch base barrier layer and the touch insulation layer. The sidewall protection portion S is arranged on a side of the first sub-pad P11 away from the base substrate 100 and completely covers the sidewall of the first sub-pad P11, and an end of the sidewall protection portion S away from the base substrate 100 is located on the side of the first sub-pad P11 away from the base substrate 100. That is, the end of the sidewall protection portion S away from the base substrate 100 is not arranged inside the first sub-pad P11, thereby avoiding the problem of cracking of the first sub-pad P11 during the pressure bonding process.

According to some exemplary embodiments, referring to FIG. 7 to FIG. 10, the connecting wire L is a double-layer wire, and the connecting wire L includes a first sub-layer L1 and a second sub-layer L2 on a side of the first sub-layer L1 away from the base substrate 100.

According to some exemplary embodiments, referring to FIG. 7, FIG. 9 or FIG. 10, the first sub-layer L1 is arranged in the first source drain metal layer SD1, and the second sub-layer L2 is arranged in the second source drain metal layer SD2.

According to some exemplary embodiments, referring to FIG. 8, the first sub-layer L1 is arranged in the second source drain metal layer SD2, the second sub-layer L2 is arranged in the third source drain metal layer SD3, and a second passivation layer PV2 is arranged between the first sub-layer L1 and the second sub-layer L2.

According to some exemplary embodiments, the second passivation layer has a via hole, and the first sub-layer L1 and the second sub-layer L2 are connected in parallel through the via hole, so as to reduce the impedance of the connecting wire L.

According to some exemplary embodiments, the second pad P2 is arranged in the driving function layer 200, that is, the second pad P2 is arranged in at least part of the driving metal layers.

According to some exemplary embodiments, the second pad P2 is arranged in at least one of the first gate metal layer, the first source drain metal layer or the second source drain metal layer.

According to some exemplary embodiments, the second pad P2 is arranged in at least one of the first gate metal layer, the first source drain metal layer, the second source drain metal layer or the third source drain metal layer.

For example, referring to FIG. 7, the second pad P2 is arranged in the first source drain metal layer SD1 and the second source drain metal layer SD2. That is, the second pad P2 has two stacked pad portions, where a pad portion close to the base substrate 100 is arranged in the first source drain metal layer SD1, and a pad portion away from the base substrate 100 is arranged in the second source drain metal layer SD2.

For example, referring to FIG. 8, the second pad P2 is arranged in the second source drain metal layer SD2 and the third source drain metal layer SD3. That is, the second pad P2 has two stacked pad portions, where a pad portion close to the base substrate 100 is arranged in the second source drain metal layer SD2, and a pad portion away from the base substrate 100 is arranged in the third source drain metal layer SD3.

For example, referring to FIG. 9, the second pad P2 is arranged in the first gate metal layer GATE1, the first source drain metal layer SD1, the second source drain metal layer SD2 and the third source drain metal layer SD3. That is, the second pad P2 has four stacked pad portions, where a pad portion closest to the base substrate 100 is arranged in the first gate metal layer GATE1, two middle pad portions are respectively arranged in the first source drain metal layer SD1 and the second source drain metal layer SD2, and a pad portion farthest away from the base substrate 100 is arranged in the third source drain metal layer SD3.

For example, referring to FIG. 10, the second pad P2 is arranged in the first gate metal layer GATE1, the first source drain metal layer SD1 and the second source drain metal layer SD2. That is, the second pad P2 has three stacked pad portions, where a pad portion closest to the base substrate 100 is arranged in the first gate metal layer GATE1, a middle pad portion is arranged in the first source drain metal layer SD1, and a pad portion farthest away from the base substrate 100 is arranged in the second source drain metal layer SD2.

According to some exemplary embodiments, a sidewall protection portion is provided at the sidewall of the second pad P2.

According to some exemplary embodiments, the connecting wire L and the insulation protection portion Q are both arranged in the driving function layer 200.

FIG. 11 shows a schematic cross-sectional view of a display substrate along C-C′ in FIG. 3 according to some exemplary embodiments of the present disclosure.

According to some exemplary embodiments, referring to FIG. 11, the connecting wire L includes a first sub-layer L1 and a second sub-layer L2. The first sub-layer L1 is directly connected to the first sub-pad P11, the second sub-layer L2 is arranged on a side of the first sub-layer L1 away from the base substrate 100, and the second sub-layer L2 is spaced apart from the first sub-pad P11 and exposes a first portion L11 of the first sub-layer L1. The insulation protection portion Q is arranged on a side of the first sub-layer L1 away from the base substrate 100 and covers at least the first portion L11 of the first sub-layer L1.

According to some exemplary embodiments, the insulation protection portion Q is arranged between the first sub-layer L1 and the second sub-layer L2 and has a via hole H. The via hole H is arranged on a side of the first portion L11 away from the first sub-pad P11, and the first sub-layer L1 and the second sub-layer L2 are connected through the via hole H. The first sub-layer L1 and the second sub-layer L2 are connected in parallel at the via hole H, so as to reduce the impedance of the connecting wire L.

According to some exemplary embodiments, referring to FIG. 11, the first sub-layer L1 is arranged in the first source drain metal layer SD1, the second sub-layer L2 is arranged in the second source drain metal layer SD2, and the insulation protection portion Q is arranged in the first passivation layer PV1.

According to some exemplary embodiments, the first sub-layer L1 is arranged in the first source drain metal layer, the second sub-layer L2 is arranged in the third source drain metal layer, and the insulation protection portion Q is arranged in the first passivation layer or the second passivation layer.

According to some exemplary embodiments, the first sub-layer L1 is arranged in the second source drain metal layer, the second sub-layer L2 is arranged in the third source drain metal layer, and the insulation protection portion Q is arranged in the second passivation layer.

According to some exemplary embodiments, the first sub-pad P11 is arranged in at least one of the first gate metal layer, the first source drain metal layer or the second source drain metal layer.

For example, referring to FIG. 11, the first sub-pad P11 is arranged in the first gate metal layer, the first source drain metal layer and the second source drain metal layer. That is, the first sub-pad P11 has three stacked pad portions, including a first pad portion P11a on the base substrate 100, a second pad portion P11b on a side of the first pad portion P11a away from the base substrate 100, and a third pad portion P11c on a side of the second pad portion P11b away from the base substrate 100. The first pad portion P11a is arranged in the first gate metal layer GATE1, the second pad portion P11b is arranged in the first source drain metal layer SD1, and the third pad portion P11c is arranged in the second source drain metal layer SD2.

According to some exemplary embodiments, the first sub-pad P11 is arranged in at least one of the first gate metal layer, the first source drain metal layer, the second source drain metal layer or the third source drain metal layer.

For example, the first sub-pad P11 is arranged in the first gate metal layer, the first source drain metal layer, the second source drain metal layer and the third source drain metal layer. That is, the first sub-pad P11 has four stacked pad portions, including a first pad portion on the base substrate 100, a second pad portion on a side of the first pad portion away from the base substrate, a third pad portion on a side of the second pad portion away from the base substrate, and a fourth pad portion on a side of the third pad portion away from the base substrate. The first pad portion is arranged in the first gate metal layer, the second pad portion is arranged in the first source drain metal layer, the third pad portion is arranged in the second source drain metal layer, and the fourth pad portion is arranged in the third source drain metal layer.

According to some exemplary embodiments, referring to FIG. 11, the second pad P2 is arranged in the first source drain metal layer SD1 and the second source drain metal layer SD2.

In another aspect, a display apparatus including the above-mentioned display substrate is provided. The display apparatus may be a display device such as a liquid crystal display, an electronic paper, and an OLED (organic light-emitting diode) display, or may be a product or component including the display device and having touch and display functions, such as a television, a digital camera, a mobile phone, a watch, a tablet computer, a laptop computer, and a navigator.

It will be understood that the display apparatus according to some exemplary embodiments of the present disclosure has all the features and advantages of the display substrate described above, and the features and advantages may be referred to the description of the display substrate above, which will not be repeated here.

As used in the present disclosure, the terms “substantially”, “about”, “approximately” and other similar terms are used as terms of approximation rather than as terms of degree, and they are intended to account for inherent deviations in measured or calculated values that are recognized by those of ordinary skill in the art. Taking into account factors such as process fluctuations, measurement problems, errors associated with measurement of particular quantities (i.e., limitations of a measurement system), the term “about” or “approximately” used herein includes the stated values, and indicates that the particular values are within acceptable tolerances as determined by those of ordinary skill in the art. For example, “about” may mean within one or more standard deviations, or within ±10% or ±5% of the stated values.

Although some embodiments according to the general inventive concept of the present disclosure have been illustrated and described, those of ordinary skill in the art will understand that changes may be made to these embodiments without departing from the principles and spirit of the general inventive concept of the present disclosure, and the scope of the present disclosure is defined by the claims and their equivalents.

1. A display substrate, comprising a display area and a peripheral area around the display area, the peripheral area comprising a first bonding area; the display substrate comprising:
a base substrate;
first pads arranged on the base substrate and in the first bonding area, wherein the first pads comprise a plurality of first sub-pads arranged at intervals and a plurality of second sub-pads arranged at intervals, and the plurality of second sub-pads are arranged on a side of the plurality of first sub-pads close to the display area;
a driver chip arranged on the first pad, wherein an edge of the driver chip away from the display area protrudes from an edge of the first sub-pad;
a connecting wire arranged on the base substrate, wherein one end of the connecting wire is electrically connected to the first sub-pad, and the other end of the connecting wire extends in a direction away from the display area; and
an insulation protection portion arranged on a side of the connecting wire away from the base substrate, wherein the insulation protection portion covers at least a portion of the connecting wire,
wherein an orthographic projection of the edge of the driver chip away from the display area on the base substrate falls within an orthographic projection of the insulation protection portion on the base substrate.

2. The display substrate according to claim 1, wherein the orthographic projection of the insulation protection portion on the base substrate has a first edge close to the display area and a second edge away from the display area, an orthographic projection of the driver chip on the base substrate has a third edge away from the display area, and the third edge is between the first edge and the second edge.

3. The display substrate according to claim 1, further comprising an organic insulation portion on a side of the connecting wire away from the base substrate, wherein the organic insulation portion covers a portion of the connecting wire, the organic insulation portion is spaced apart from the first sub-pad, an orthographic projection of the organic insulation portion on the base substrate has a fourth edge close to the display area, and the second edge is further away from the display area than the fourth edge; and/or
an orthographic projection of the connecting wire on the base substrate has a fifth edge close to the display area, and the first edge is flush with the fifth edge.

4. The display substrate according to claim 1, comprising:
a driving function layer on the base substrate, wherein the driving function layer comprises a plurality of driving metal layers; and
a touch function layer on a side of the driving function layer away from the base substrate.

5. The display substrate according to claim 4, wherein the connecting wire is arranged in the driving function layer, and the insulation protection portion is arranged in the touch function layer.

6. The display substrate according to claim 5, wherein the touch function layer comprises:
a touch base barrier layer on the driving function layer away from the base substrate;
a first touch metal layer on a side of the touch base barrier layer away from the driving function layer;
a touch insulation layer on a side of the first touch metal layer away from the touch base barrier layer; and
a second touch metal layer on a side of the touch insulation layer away from the first touch metal layer,
wherein the insulation protection portion is arranged in at least one of the touch base barrier layer and the touch insulation layer.

7. The display substrate according to claim 5, wherein the first sub-pad comprises a first pad sub-portion and a second pad sub-portion on a side of the first pad sub-portion away from the base substrate,
wherein the first pad sub-portion is arranged in at least part of the driving metal layers, and the second pad sub-portion is arranged in the touch function layer.

8. The display substrate according to claim 7, wherein the plurality of driving metal layers comprise:
a first gate metal layer on the base substrate;
a first source drain metal layer on a side of the first gate metal layer away from the base substrate; and
a second source drain metal layer on a side of the first source drain metal layer away from the first gate metal layer,
wherein the first pad sub-portion is arranged in at least one of the first gate metal layer, the first source drain metal layer or the second source drain metal layer; or
wherein the plurality of driving metal layers comprise:
a first gate metal layer on the base substrate;
a first source drain metal layer on a side of the first gate metal layer away from the base substrate;
a second source drain metal layer on a side of the first source drain metal layer away from the first gate metal layer; and
a third source drain metal layer on a side of the second source drain metal layer away from the first source drain metal layer,
wherein the first pad sub-portion is arranged in at least one of the first gate metal layer, the first source drain metal layer, the second source drain metal layer or the third source drain metal layer.

9. The display substrate according to claim 7, wherein the touch function layer comprises a first touch metal layer and a second touch metal layer on a side of the first touch metal layer away from the base substrate,
wherein the second pad sub-portion is arranged in at least one of the first touch metal layer and the second touch metal layer.

10. The display substrate according to claim 5, wherein the first sub-pad is arranged in at least part of the driving metal layers.

11. The display substrate according to claim 10, wherein the plurality of driving metal layers comprise:
a first gate metal layer on the base substrate;
a first source drain metal layer on a side of the first gate metal layer away from the base substrate; and
a second source drain metal layer on a side of the first source drain metal layer away from the first gate metal layer,
wherein the first sub-pad is arranged in at least one of the first gate metal layer, the first source drain metal layer or the second source drain metal layer; or
wherein the plurality of driving metal layers comprise:
a first gate metal layer on the base substrate;
a first source drain metal layer on a side of the first gate metal layer away from the base substrate;
a second source drain metal layer on a side of the first source drain metal layer away from the first gate metal layer; and
a third source drain metal layer on a side of the second source drain metal layer away from the first source drain metal layer,
wherein the first sub-pad is arranged in at least one of the first gate metal layer, the first source drain metal layer, the second source drain metal layer or the third source drain metal layer.

12. The display substrate according to claim 4, wherein the connecting wire is arranged in the driving function layer, and the insulation protection portion is arranged in the driving function layer.

13. The display substrate according to claim 12, wherein the connecting wire comprises:
a first sub-layer adjacent to the first sub-pad and directly connected to the first sub-pad; and
a second sub-layer on a side of the first sub-layer away from the base substrate, the second sub-layer being spaced apart from the first sub-pad and exposing a first portion of the first sub-layer,
wherein the insulation protection portion is arranged on a side of the first sub-layer away from the base substrate and covers at least the first portion of the first sub-layer.

14. The display substrate according to claim 13, wherein the insulation protection portion is arranged between the first sub-layer and the second sub-layer, the insulation protection portion has a via hole on a side of the first portion away from the first sub-pad, and the first sub-layer and the second sub-layer are connected through the via hole.

15. The display substrate according to claim 13, wherein the driving function layer comprises:
a first source drain metal layer;
a first passivation layer on a side of the first source drain metal layer away from the base substrate; and
a second source drain metal layer on a side of the first passivation layer away from the first source drain metal layer,
wherein the first sub-layer is arranged in the first source drain metal layer, the second sub-layer is arranged in the second source drain metal layer, and the insulation protection portion is arranged in the first passivation layer; or
wherein the driving function layer comprises:
a first source drain metal layer;
a first passivation layer on a side of the first source drain metal layer away from the base substrate;
a second source drain metal layer on a side of the first passivation layer away from the first source drain metal layer;
a second passivation layer on a side of the second source drain metal layer away from the first passivation layer; and
a third source drain metal layer on a side of the second passivation layer away from the second source drain metal layer,
wherein the first sub-layer is arranged in the first source drain metal layer, the second sub-layer is arranged in the second source drain metal layer, and the insulation protection portion is arranged in the first passivation layer; or, the first sub-layer is arranged in the second source drain metal layer, the second sub-layer is arranged in the third source drain metal layer, and the insulation protection portion is arranged in the second passivation layer.

16. The display substrate according to claim 1, wherein the display substrate further comprises a sidewall protection portion covering at least a portion of a sidewall of the first sub-pad, and the sidewall protection portion is made of an insulation material.

17. The display substrate according to claim 5, wherein the display substrate further comprises a sidewall protection portion covering at least a portion of a sidewall of the first sub-pad, and the sidewall protection portion and the insulation protection portion are arranged in a same layer.

18. The display substrate according to claim 4, wherein the peripheral area further comprises a second bonding area on a side of the first bonding area away from the display area; and
the display substrate further comprises a second pad arranged on the base substrate and in the second bonding area, the other end of the connecting wire is electrically connected to the second pad, and the insulation protection portion extends from the end of the connecting wire close to the first sub-pad to the other end of the connecting wire close to the second pad.

19. A display substrate, comprising a display area and a peripheral area located around the display area, the peripheral area comprising a first bonding area; and the display substrate comprises:
a first pad arranged on a base substrate and in the first bonding area, wherein the first pad comprises a plurality of first sub-pads arranged at intervals and a plurality of second sub-pads arranged at intervals, and the plurality of second sub-pads are on a side of the plurality of first sub-pads close to the display area;
a driver chip arranged on the first pad, wherein an edge of the driver chip away from the display area protrudes from an edge of the first sub-pad;
a connecting wire arranged on the base substrate, wherein one end of the connecting wire is electrically connected to the first sub-pad, and the other end of the connecting wire extends in a direction away from the display area;
an insulation protection portion on a side of the connecting wire away from the base substrate, wherein the insulation protection portion covers at least a portion of the connecting wire; and
a sidewall protection portion covering at least a portion of a sidewall of the first pad, the sidewall protection portion being made of an insulation material,
wherein the insulation protection portion and the sidewall protection portion are arranged in a same layer, and an orthographic projection of the sidewall protection portion on the base substrate at least partially overlaps with an orthographic projection of the driver chip on the base substrate.

20. A display apparatus comprising a display substrate according to claim 1.
